(19) United States
(12) Patent Application Publication
(10) Pub. No.: US 2021/0110985 A1
(43) Pub. Date: Apr. 15, 2021

(54) Electromagnetic Coupler

(71) Applicant: Kay C Robinson, JR., Detroit, MI (US)

(72) Inventor: Kay C Robinson, JR., Detroit, MI (US)

(21) Appl. No.: 16/599,074

(22) Filed: Oct. 10, 2019

(51) Int. Cl. H01H 47/32; H01H 47/36; H03K 17/56; H03K 17/0814

(52) U.S. Cl. CPC H01H 47/325; H03K 17/0814; H03K 17/56; H01H 47/36

(57) ABSTRACT

The electromagnetic coupler uses a coil to induce voltage onto a transistor. By controlling the amount of current that flows through the coil, one is able to can control the strength of the magnetic field emitted by the inductor. And by the controlling the q-point of the transistor, the amount voltage and current induced onto the transistor it can then potentially be used as a switch or an amplifier without any electrical/electronic connection to the internal coil. The use of a transistor enables high speed switching and the potential amplification of communication signals.

### BACKGROUND OF THE INVENTION

The original purpose of invention was to create a relay with the ability operate at high speeds. Relays use electromagnetism to mechanically operate a switch. This causes a contact bounce or debouncing effect. Because of the mechanical switch, the speeds or frequencies at which the relay can operate are limited. By replacing the mechanical switch with an electronic one the operating potential of the relay increases.

### SUMMARY OF THE INVENTION

Using the same principal of how the relay operates, an electromagnet to induce and transfer energy, and replacing the mechanical switch with a transistor the operating potential of the relay as well as potential uses increases significantly. Also depending on how the transistor is biased it can even be used as an amplifier. Electric power and electronic communication can be transferred from the coil to the transistor without any electrical/electronic connection.

### BRIEF DESCRIPTION OF THE DRAWINGS

FIG. 1 is a coil in the same casing as an BJT transistor.

FIG. 2 is a coil in the same casing as an FET transistor.

FIG. 3 is a coil in the same casing as an UJT transistor.

FIG. 4 is a coil in the same casing as an PUT transistor.

FIG. 5 is a coil in the same casing as an SCR thyristor.

FIG. 6 is a coil in the same casing as an TRIAC thyristor.

FIG. 7 is a coil in the same casing as an GTO thyristor.

FIG. 8 is a coil in the same casing as an IGBT transistor.

FIG. 9 is a circuit drawing describing the operation of the invention using a BJT transistor.

FIG. 10 is a circuit drawing describing the operation of the invention using a FET transistor.

FIG. 11 is a circuit drawing describing the operation of the invention using a UJT transistor.

FIG. 12 is a circuit drawing describing the operation of the invention using a PUT transistor.

FIG. 13 is a circuit drawing describing the operation of the invention using a SCR thyristor.

FIG. 14 is a circuit drawing describing the operation of the invention using a TRIAC thyristor.

FIG. 15 is a circuit drawing describing the operation of the invention using a GTO thyristor.

FIG. 16 is a circuit drawing describing the operation of the invention using a IGBT transistor.

### DETAILED DESCRIPTION

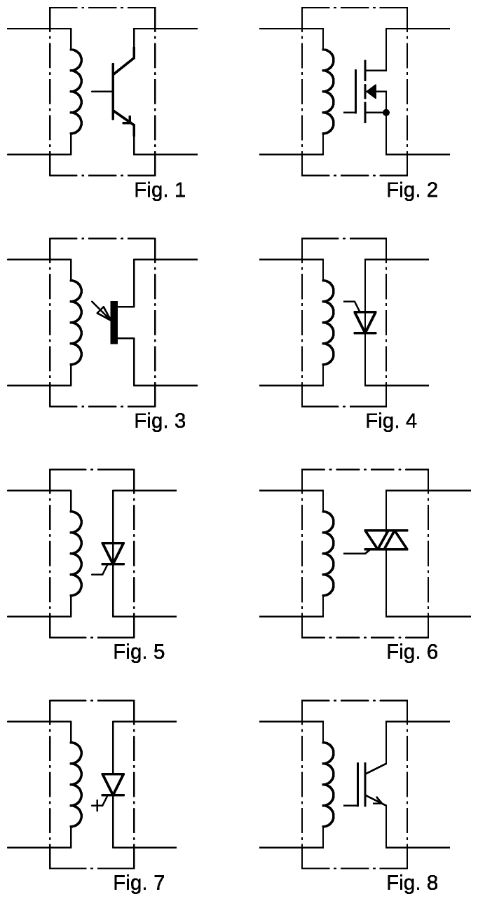

FIG. 1 uses a coil in the same casing as a BJT transistor. When an electrical current passes through the coil and is energized, an electromagnetic field will develop and induce a voltage onto the base of the transistor. Depending on the q-point of the internal BJT transistor the induced voltage as well as current will be amplified, or the transistor will act as a switch moving between its saturation and cutoff modes. This will be accomplished without any electrical/electronic connection between the coil and the BJT transistor.

FIG. 2 uses a coil in the same casing as a FET transistor. When an electrical current passes through the coil and is energized, an electromagnetic field will develop and induce a voltage onto the gate of the transistor. Depending on the q-point of the internal FET transistor the induced voltage as well as current will be amplified, or the transistor will act as a switch moving between its saturation and cutoff modes. This will be accomplished without any electrical/electronic connection between the coil and the FET transistor.

FIG. 3 uses a coil in the same casing as a UJT transistor. When an electrical current passes through the internal coil of the electromagnetic coupler and is energized, an electromagnetic field will develop and induce a voltage onto the emitter of the transistor. The electromagnetic coupler utilizing an internal UJT transistor is not meant to be used as an amplifying device but as a voltage-controlled switch and will have with no electrical/electronic connection to the internal coil.

FIG. 4 uses a coil in the same casing as a PUT transistor. When an electrical current passes through the coil and is energized, an electromagnetic field will develop and induce a voltage onto the gate of the transistor. The electromagnetic coupler in FIG. 4 utilizing an internal PUT transistor will act similar to the electromagnetic coupler in FIG. 3 except that the peak voltage of the electromagnetic coupler in FIG. 4 can be controlled. The voltage induced will be accomplished without any electrical/electronic connection between the internal coil and the PUT transistor.

FIG. 5 uses a coil in the same casing as a SCR thyristor. When an electrical current passes through the coil and is energized, an electromagnetic field will develop and induce a voltage onto the gate of the thyristor. The internal SCR thyristor must be biased like a diode. The internal SCR of the electromagnetic coupler will not conduct until a positive voltage is induced onto its gate with, respect to its cathode, by the coil and will only conduct in one direction. This will be accomplished without any electrical/electronic connection between the internal coil and the SCR thyristor.

FIG. 6 uses a coil in the same casing as a TRIAC thyristor. When an electrical current passes through the coil and is energized, an electromagnetic field will develop and induce a voltage onto the gate of the thyristor. The electromagnetic coupler utilizing an internal TRIAC can conduct in both directions giving it the ability to control an AC power supply and can be triggered with either a positive or negative voltage induced onto the gate of the internal TRIAC. This will be accomplished without any electrical/electronic connection between the internal coil and the TRIAC thyristor.

FIG. 7 uses a coil in the same casing as a GTO thyristor. When an electrical current passes through the coil and is energized an electromagnetic field will develop and induce a voltage onto the gate of the thyristor. The electromagnetic coupler utilizing an internal GTO can be controlled with a positive voltage, relative to its cathode, to activate and negative voltage to deactivate induced onto the gate of the internal GTO. This will be accomplished without any electrical/electronic connection between the internal coil and the GTO thyristor.

FIG. 8 uses a coil in the same casing as a IGBT transistor. When an electrical current passes through the coil and is energized an electromagnetic field will gate and induce a voltage onto the gate of the transistor. Depending on the q-point of the IGBT transistor the induced voltage as well as current will be amplified, or the transistor will act as a switch moving between its saturation and cutoff modes. This will be accomplished without any electrical/electronic connection between the internal coil and the IGBT transistor.

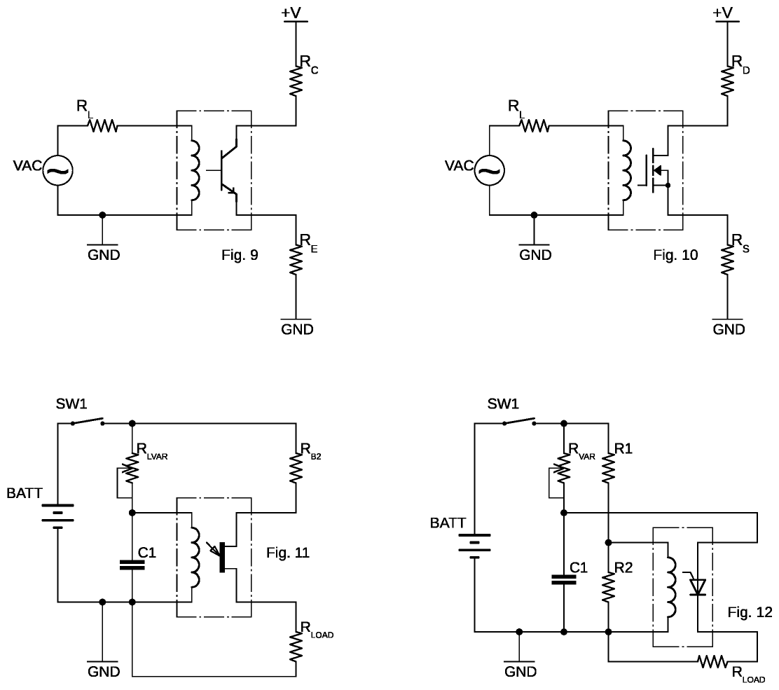

FIG. 9 is an example of one of the potential applications of the electromagnetic coupler, utilizing a BJT transistor, and is also a brief visual description of the operation of the invention. FIG. 9 uses a regular DC power source to power the internal BJT transistor of the electromagnetic coupler. The AC power source is a representation of an electronic communication source or signal. The R_{C} and R_{E} resistors are used to set the saturation current of the BJT transistor. R_{L} is used to control the current through the coil and thereby the amount of current induced onto the base of the BJT transistor while maintaining no electrical/electronic connection between the internal coil and the BJT transistor.

FIG. 10 is an example of one of the potential applications of the electromagnetic coupler, utilizing a FET transistor, and is also a brief visual description of the operation of the invention. FIG. 10 uses a regular DC power source to power the FET transistor. The AC power source is a representation of an electronic communication source or signal. The R_{D} and R_{S} resistors are used to set the saturation current of the FET transistor. R_{L} is used to control the current through the coil and thereby the amount of current induced onto the gate of the FET transistor while maintaining no electrical/electronic connection between the internal coil and the FET transistor.

FIG. 11 is an example of one of the potential applications of the electromagnetic coupler, utilizing a UJT transistor, and is also a brief visual description of the operation of the invention. FIG. 11 is an illustration of a relaxation oscillator circuit. When SW1, the switch, closes C1, the capacitor, charges by the variable resistor, R_{LVAR}. When the voltage across C1 reaches the UJT's peak value, the needed voltage will then be induced by the internal coil onto the emitter of the internal UJT. The internal UJT will turn on and conduct current driving the load while maintaining no electrical/electronic connection to the internal coil.

FIG. 12 is an example of one of the potential applications of the electromagnetic coupler, utilizing a PUT transistor, and is also a brief visual description of the operation of the invention. FIG. 12 is an illustration of a relaxation oscillator circuit. When SW1, the switch, closes C1, the capacitor, charges by means of R_{LVAR}, the variable resistor. When the internal PUT's anode to cathode exceeds induced gate by 0.7 volts C1, the capacitor, will discharge through the internal PUT and drive R_{load}. The gate to cathode voltage to be induced, overcome by C1, and activate the internal PUT will be set using a small voltage divider network of, R1 and R2, to energize the internal coil and induce a trigger voltage the internal PUT transistor of the electromagnetic coupler the PUT will turn on and conduct current driving the load while maintaining no electrical/electronic connection between the internal coil and PUT transistor.

FIG. 13 is an example of one of the potential applications of the electromagnetic coupler, utilizing an SCR thyristor, and is also a brief visual description of the operation of the invention. FIG. 13 uses a battery to power the circuit, however the internal SCR of the electromagnetic coupler will not conduct and power the load until it's required gate voltage is met. When SW1, the switch, closes the internal coil of the electromagnetic coupler will energize and induce the required voltage onto the gate of the internal SCR transistor, turning it on causing it to conduct and drive the load while maintaining no electrical/electronic connection between the internal coil and SCR thyristor.

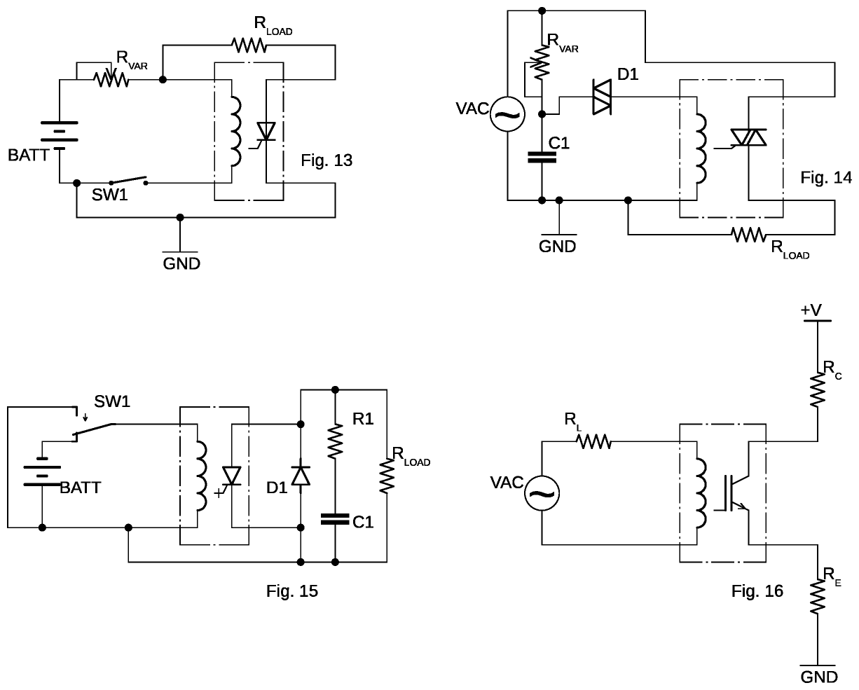

FIG. 14 is an example of one of the potential applications of the electromagnetic coupler, utilizing a TRIAC transistor, and is also a brief visual description of the operation of the invention. FIG. 14 is an ac power control circuit with the electromagnetic coupler utilizing an internal TRIAC thyristor. D1, the DIAC, will turn on when the capacitor has charged to either the positive or negative breakover voltage. Once the D1 turns on, C1, the capacitor, discharges through D1, energizing the internal coil of electromagnetic coupler. The internal coil will then induce a voltage onto the gate of the internal TRIAC of the electromagnetic coupler, triggering it into conduction. The internal TRIAC of the will then connect the ac power supply to load. Rᵥₐᵣ is used to adjust the time it takes to charge and discharge C1 or RC time constant. The RC time constant of C1 will set the time when D1 will activate and energize the internal coil of the electromagnetic coupler and induce a trigger voltage onto the gate of the internal TRIAC thyristor of the electromagnetic coupler while maintaining no electrical/electronic connection between the internal coil and the TRIAC.

FIG. 15 is an example of one of the potential applications of the electromagnetic coupler, utilizing a GTO thyristor, and is also a brief visual description of the operation of the invention. FIG. 15 is a basic drive circuit with the electromagnetic coupler utilizing an internal GTO thyristor. When SW1, the switch, is connected the positive contact it will energize the internal coil of the electromagnetic coupler which will then induce a positive voltage onto the gate of the internal GTO of the electromagnetic coupler, turning it on and causing it to conduct. The voltage will then be rectified by D1, the diode and filtered by C1, the capacitor. When SW1 is connected to the negative contact it will energize the internal coil of the electromagnetic coupler which will then induce a negative voltage onto the gate of the internal GTO turning it off and stopping it from conducting while maintaining no electrical/electronic connection between the internal coil and the GTO thyristor.

FIG. 16 is an example of one of the potential uses of the electromagnetic coupler, utilizing a IGBT transistor, and is also a brief visual description of the operation of the invention. FIG. 16 uses a regular DC power source to turn on the IGBT transistor. The AC power source is a representation of an electronic communication source or signal. The R_{D} and R_{S} resistors are used to set the saturation current of the IGBT transistor. R_{L} is used to control the current through the coil and thereby the amount of current induced unto the gate of the IGBT transistor while maintaining no electrical/electronic connection between the internal coil and the IGBT transistor.

1. An electronic component comprising:
a) an inductor in the same housing as a BJT transistor;
b) an inductor in the same housing as a FET transistor;
c) an inductor in the same housing as a UJT transistor;
d) an inductor in the same housing as a PUT transistor;
e) an inductor in the same housing as a SCR thyristor;
f) an inductor in the same housing as a TRIAC thyristor;
g) an inductor in the same housing as a GTO thyristor;
h) an inductor in the same housing as a IGBT transistor.

2. An apparatus as in claim 1 wherein said inductor (coil) is able to develop an electromagnetic field so as to induce a voltage onto the base of said BJT transistor within the same apparatus.

3. An apparatus as in claim 1 wherein said inductor (coil) is able to develop an electromagnetic field so as to induce a voltage onto the gate of said FET transistor within the same apparatus.

4. An apparatus as in claim 1 wherein said inductor (coil) is able to develop an electromagnetic field so as to induce a voltage onto the emitter of said UJT transistor within the same apparatus.

5. An apparatus as in claim 1 wherein said inductor (coil) is able to develop an electromagnetic field so as to induce a voltage onto the gate of said PUT transistor within the same apparatus.

6. An apparatus as in claim 1 wherein said inductor (coil) is able to develop an electromagnetic field so as to induce a voltage onto the gate of said SCR thyristor within the same apparatus.

7. An apparatus as in claim 1 wherein said inductor (coil) is able to develop an electromagnetic field so as to induce a voltage onto the gate of said TRIAC thyristor within the same apparatus.

8. An apparatus as in claim 1 wherein said inductor (coil) is able to develop an electromagnetic field so as to induce a voltage onto the gate of said GTO thyristor within the same apparatus.

9. An apparatus as in claim 1 wherein said inductor (coil) is able to develop an electromagnetic field so as to induce a voltage onto the gate of said IGBT transistor within the same apparatus.
